(19) United States
(12) Patent Application Publication
(10) Pub. No.: US 2011/0065245 A1
(43) Pub. Date: Mar. 17, 2011

(54) METHOD FOR FABRICATING MOS TRANSISTOR

(76) Inventors: Jei-Ming Chen, Tainan City (TW); Kuo-Chih Lai, Tai-Nan City (TW); Teng-Chun Tsai, Tainan City (TW); Hsiu-Lien Liao, Tai-Chung City (TW)

(21) Appl. No.: 12/558,565

(22) Filed: Sep. 13, 2009

(51) Int. Cl. H01L 21/336

(52) U.S. Cl. 438/197; 438/758; 438/597; 257/E21.409

(57) ABSTRACT

A method for fabricating a metal-oxide semiconductor (MOS) transistor is disclosed. The method includes the steps of: providing a semiconductor substrate; forming a gate structure on the semiconductor substrate and a source/drain region in the semiconductor substrate adjacent to two sides of the gate structure; covering a stress layer on the gate structure and the source/drain region; etching away the stress layer to form a plurality of openings with larger top and smaller bottom to expose surface of the gate structure and the source/drain region; forming a metal layer in the openings; and using the stress layer as a salicide block to react the metal layer with the gate structure and the source/drain region for forming a plurality of silicide layers.

### BACKGROUND OF THE INVENTION

1. Field of the Invention

The invention relates to a method for fabricating MOS transistor, and more particularly, to a method of utilizing high compressive film as salicide block for increasing formation of silicide.

2. Description of the Prior Art

Field effect transistors are important electronic devices in the fabrication of integrated circuits, and as the size of the semiconductor device becomes smaller and smaller, the fabrication of the transistors also improves and is constantly enhanced for fabricating transistors with smaller sizes and higher quality.

In the conventional method of fabricating transistors, a gate structure is first formed on a substrate, and a lightly doped drain (LDD) is formed on the two corresponding sides of the gate structure. Next, a spacer is formed on the sidewall of the gate structure and an ion implantation process is performed to form a source/drain region within the substrate by utilizing the gate structure and spacer as a mask. In order to incorporate the gate, source, and drain into the circuit, contact plugs are often utilized for interconnection purposes, in which the contact plugs are composed of conducting metals such as tungsten and copper. Nevertheless, the interconnection between the contact plugs and the silicon material of the gate structure and the source/drain region is usually poor, hence a silicide material is often formed over the surface of the gate structure and the source/drain region to improve the ohmic contact between the contact plugs and the gate structure and the source/drain region.

Today, the process known as self-aligned silicide (salicide) process has been widely utilized to fabricate silicide materials, in which a source/drain region is first formed, a metal layer comprised of cobalt, titanium, or nickel is disposed on the source/drain region and the gate structure, and a rapid thermal process (RTP) is performed to react the metal layer with the silicon contained within the gate structure and the source/drain region to form a metal silicide for reducing the sheet resistance of the source/drain region.

Typically, a salicide block (SAB) is utilized in a salicide process to define the region where silicides are being formed. For instance, a salicide block composed of nitrides is deposited on a semiconductor substrate before the formation of metal layer, and a portion of the salicide block is etched away to expose the gate structure and the source/drain region on the semiconductor substrate.

However, the opening formed in the salicide block following conventional salicide process is usually too small to collect enough metal sputtered during the salicide process. This causes poor formation of silicide layer on surface of the gate structure and the source/drain region and further results in poor electrical connection between the contact plug and the gate structure and the source drain region, and deteriorates the performance of the MOS transistor substantially.

### SUMMARY OF THE INVENTION

It is an objective of the present invention to provide a method for fabricating MOS transistor for improving the issue of poor silicide formation produced with current silicide process.

According to a preferred embodiment of the present invention, a method for fabricating a metal-oxide semiconductor (MOS) transistor is disclosed. The method includes the steps of: providing a semiconductor substrate; forming a gate structure on the semiconductor substrate and a source/drain region in the semiconductor substrate adjacent to two sides of the gate structure; covering a stress layer on the gate structure and the source/drain region; etching away the stress layer to form a plurality of openings with larger top and smaller bottom to expose surface of the gate structure and the source/drain region; forming a metal layer in the openings; and using the stress layer as a salicide block to react the metal layer with the gate structure and the source/drain region for forming a plurality of silicide layers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a MOS transistor according to a preferred embodiment of the present invention.

FIG. 6 illustrates a comparative table regarding the deformation of a semiconductor substrate (or wafer) according to a preferred embodiment of the present invention.

### DETAILED DESCRIPTION

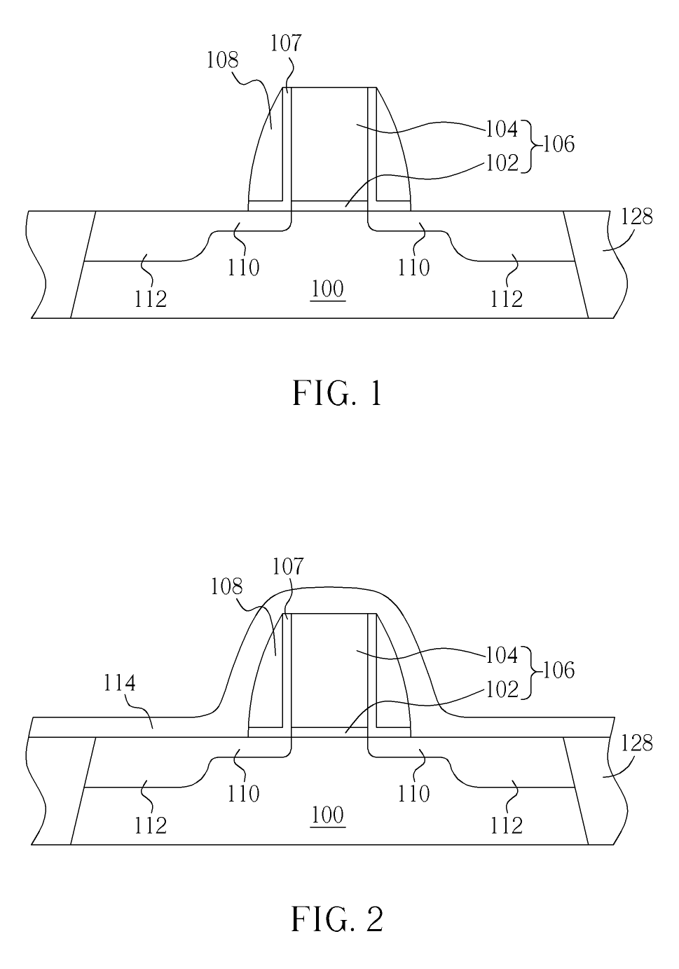

Referring to FIGS. 1-5, FIGS. 1-5 illustrate a method for fabricating a MOS transistor according to a preferred embodiment of the present invention. As shown in FIG. 1, a substrate 100, such as a wafer or a silicon-on-insulator (SOI) substrate is provided. Preferably, the semiconductor substrate 100 may include structures such as gate electrode 104, source/drain regions 112, isolation regions 128, word lines, or resistors depending on different product demands and fabrication processes. According to the preferred embodiment of the present invention, a gate structure 106 and source/drain region 112 of a MOS transistor are utilized as an example, as shown in FIGS. 1-5. As shown in FIG. 1, the gate structure 106 includes a gate dielectric layer 102 and gate electrode 104. The gate dielectric layer 102 is preferably composed of insulating material such as silicon nitrides, oxides, oxynitrides, or metal oxides, and the gate conductive layer 104 is composed of conductive material such as doped polysilicon.

Next, a lightly doped ion implantation process is performed by using the gate electrode 104 as mask to implant dopants into the semiconductor substrate 100 adjacent to two sides of the gate conductive layer 104 for forming a source/drain extension or a lightly doped source/drain 110. The implanted dopants are preferably selected according to the type of MOS transistor being fabricated. For instance, n-type dopants including phosphorus or arsenic would be implanted for fabricating a NMOS transistor, whereas p-type dopants including boron would be used for a PMOS transistor. Additionally, a spacer (not shown) could be selectively formed prior to the formation of the source/drain extension or the lightly doped source/drain 110. By doing so, this selectively formed spacer and the gate electrode 104 could be using as a mask during the lightly doped ion implantation process.

A liner 107 composed of silicon oxide and one or more spacer 108 composed of silicon nitride compound are selectively formed on the sidewall of the gate structure 106, in which the liner 107 and the spacer 108 could be composed of any dielectric material. Next, a heavily doped ion implantation is performed by using the gate electrode 104 and the spacer 108 as mask to implant heavy dopants into the semiconductor substrate 100 for forming a source/drain region 112. Similar to the ion implantation conducted for the aforementioned lightly doped source/drain 110, dopants implanted for a NMOS transistor would include phosphorus or arsenic, whereas dopants implanted for a PMOS transistor would include boron. Next, a thermal annealing process is performed by using a temperature between 1000° C. to 1020° C. to activate the dopants within the semiconductor substrate 100 and repair the damage of the crystal lattice structure of the semiconductor substrate 100 caused during the ion implantation process.

In addition to the aforementioned process, the order for fabricating the spacer, the lightly doped source/drain and the source/drain region could be adjusted according to the demand of the product, which are all within the scope of the present invention. For instance, in one embodiment, one or more spacer could be formed, the source/drain is formed thereafter, and after removing the spacer or the outer most layer of the spacer, ion implantation is conducted to form the lightly doped drain region. In another embodiment, two recesses could be formed in the substrate with respect to two sides of the gate structure prior to the formation of the source drain region, and an epitaxial layer could be grown through selective epitaxial growth process in the two recesses thereafter. The epitaxial layer is preferably composed of material suitable for NMOS transistor, such as SiC, or material suitable for PMOS transistor, such as SiGe.

As shown in FIG. 2, a stress layer 114 composed of nitrides is formed on the semiconductor substrate 100 to cover the gate structure 106, the spacer 108, and the source/drain region 112. In this embodiment, the stress layer 114 is preferably a high compressive stress layer having compressive strain, in which the deposition temperature of the stress layer 114 is between 200° C. and 600° C., and preferably at 400° C. According to an embodiment of the present invention, NH₃ could be injected before the deposition of the stress layer 114 for increasing the stress of the stress layer 114. In this embodiment, the stress of the stress layer 114 is between −0.5 Gpa and −5 GPa, and preferably at −3.5 GPa.

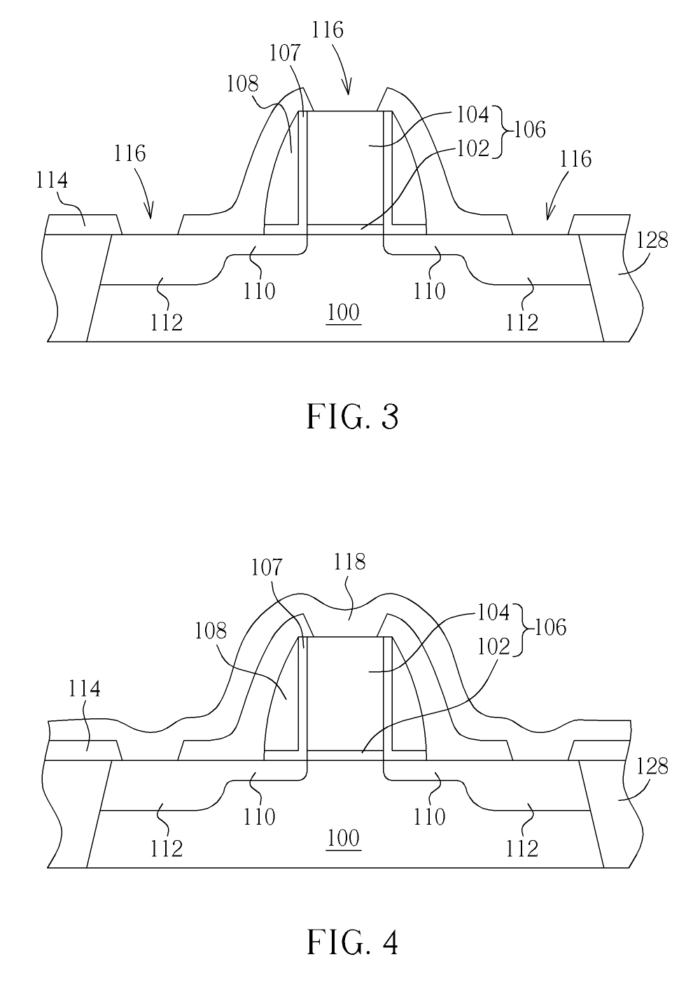

Next, a patterned photoresist (not shown) is formed on region of the semiconductor substrate 100 not intended to form silicide layer, such as regions outside the gate structure 106 and the source/drain region 112. As shown in FIG. 3, an etching process is performed by using the patterned photoresist as mask to remove a portion of the stress layer for forming a plurality of openings 116 exposing a portion of the gate electrode 104 and source/drain region 112 underneath, such that the stress layer 114 with the openings 116 is preferably utilized as a salicide block. According to a preferred embodiment of the present invention, inclined sidewalls are formed in the stress layer 114 to define a plurality of openings 116 with larger top and smaller bottom as a portion of the stress layer 114 is removed. In other words, the top of the openings 116 exposing the gate structure 106 and the source/drain region 112 has a substantially larger surface area, whereas the bottom of the opening 116 has a substantially lower surface area.

A salicide process is then conducted to form silicide layers. As shown in FIG. 4, a sputtering process is performed to form a metal layer 118 on surface of the stress layer 114, the gate structure 106, and the source/drain region 112 while filling the openings 116. The metal layer 118 is selected from a group consisting of tungsten, cobalt, titanium, nickel, platinum, palladium, and molybdenum, and a cap layer (not shown) composed of TiN could also be formed on surface of the metal layer 118 selectively. It should be noted the stress layer 114 having compressive strain is preferably utilized as a salicide block in this embodiment, in which the openings 116 with larger top and smaller bottom formed in the stress layer 114 are used to increase the ability for gathering metal material during the metal sputtering process. As more metals are gathered in the openings 116 with larger top and smaller bottom, the stability between the connection of the contact plugs and the gate electrode 104 and the source/drain region 112 is improved substantially.

A rapid thermal annealing process is performed to heat the semiconductor substrate 100 to 200-400° C. The thermal anneal preferably transforms the metal layer 118 contacting the gate electrode 104 composed of silicon and the source/drain region 112 to a silicide layer 120. After the rapid thermal annealing process, an etching process is performed by utilizing a conventional wet etching mixture including ammonia, hydrogen peroxide, hydrochloric acid, sulfuric acid, nitric acid, and acetic acid to remove un-reacted metal layer 118 and the stress layer 114.

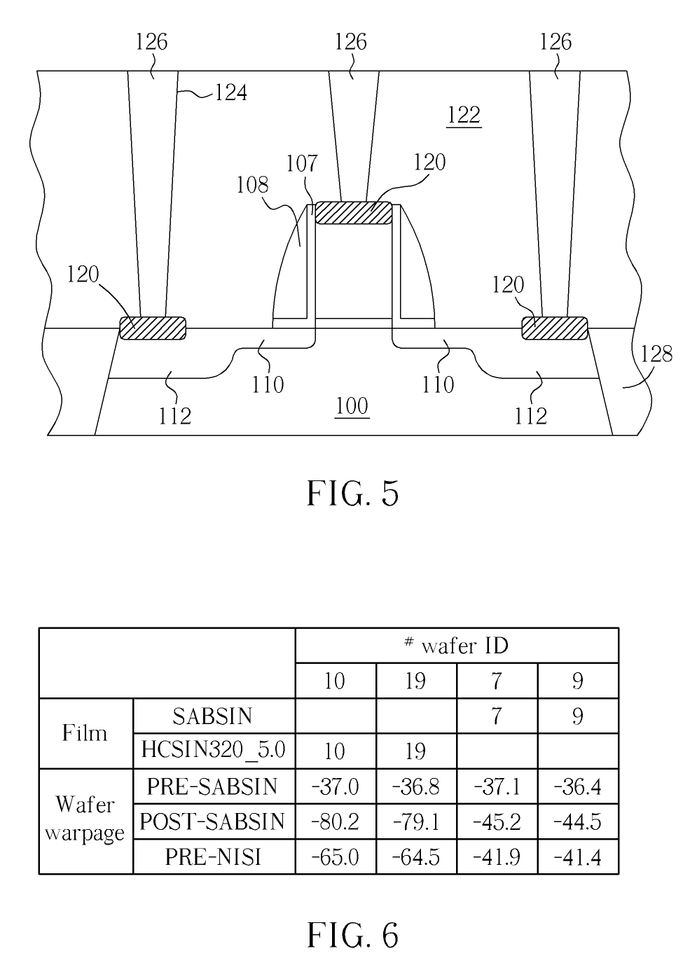

As shown in FIG. 5, an interlayer dielectric layer 122 is deposited on the semiconductor substrate 100 to cover the gate structure 106 and the source/drain region 112. The interlayer dielectric layer 122 could be composed of nitrides, oxides, carbides, low-k dielectric material or combination thereof. Moreover, a contact etch stop layer (CESL) with tensile or compressive stress depending on the nature of the NMOS or PMOS transistor could be formed selectively before the formation of the interlayer dielectric layer 122.

Next, a contact plug fabrication is performed by using a patterned photoresist (not shown) as mask to etch through the interlayer dielectric layer 122 for forming a plurality of contact openings 124 exposing the silicide layer 120 on top of the gate structure 106 and the source/drain region 112. A metal composed of tungsten or other conductors is then deposited in the contact openings 124 for forming a plurality of contact plugs 126 electrically connecting the silicide layer 120. This completes the formation of a MOS transistor with silicides.

Referring to FIG. 6, FIG. 6 illustrates a comparative table regarding the deformation of a semiconductor substrate (or wafer) according to a preferred embodiment of the present invention. As shown in FIG. 6, wafers labeled 10 and 19 are the ones fabricated with compressive salicide block, while wafers labeled 7 and 9 are the ones fabricated with salicide blocks with no compressive stress. Preferably, the deformation of the semiconductor substrate (or wafer) is less than −50 μm. Taking the wafer labeled 10 for example, the deformation obtained before the formation of the compressive salicide block is about −37.0-50 μm, the deformation obtained after the formation of the compressive salicide block is about −80.2 μm, and the deformation obtained after the formation of the silicide layer is about −65.0 μm.

If compared with wafers fabricated with salicide block having no compressive stress (such as wafers labeled 7 and 9), it is found that the degree of deformation of the wafers (labeled 10 and 19) fabricated with salicide block having compressive stress of the present invention is substantially greater. By combining the compressive stress of the stress layer and the deformation of the wafer, a plurality of openings with larger top and smaller bottom are formed in the stress layer to increase the ability for collecting more metal from the salicide process. As more metals are gathered in these openings with larger top and smaller bottom, the stability between the connection of the contact plugs and the silicide layers is improved substantially.

Those skilled in the art will readily observe that numerous modifications and alterations of the device and method may be made while retaining the teachings of the invention.

What is claimed is:

1. A method for fabricating a metal-oxide semiconductor (MOS) transistor, comprising:
providing a semiconductor substrate;
forming a gate structure on the semiconductor substrate and a source/drain region in the semiconductor substrate adjacent to two sides of the gate structure;
covering a stress layer on the gate structure and the source/drain region;
etching away the stress layer to form a plurality of openings with larger top and smaller bottom to expose surface of the gate structure and the source/drain region;
forming a metal layer in the openings; and
using the stress layer as a salicide block to react the metal layer with the gate structure and the source/drain region for forming a plurality of silicide layers.

2. The method of claim 1, further comprising forming a spacer on sidewall of the gate structure before covering the stress layer.

3. The method of claim 1, wherein the stress layer comprises a compressive stress layer.

4. The method of claim 3, wherein the stress of the compressive stress layer is between −0.5 Gpa and −5 GPa.

5. The method of claim 1, wherein the temperature for forming the stress layer is between 200° C. and 600° C.

6. The method of claim 1, further comprising injecting ammonia (NH₃) before covering the stress layer for increasing the stress of the stress layer.

7. The method of claim 1, wherein the deformation of the semiconductor substrate is less than −50 μm.
